(19) United States
(12) Patent Application Publication
(10) Pub. No.: US 2011/0094558 A1
(43) Pub. Date: Apr. 28, 2011

(54) GREENHOUSE USING TRANSPARENT SOLAR BATTERY

(75) Inventors: Mun Kee CHOI, Daejeon-city (KR); Soo Young OH, Daejeon-city (KR); Yong Seok JUN, Daejeon-city (KR); Hunkyun PAK, Daejeon-city (KR)

(73) Assignee: ELECTRONICS AND TELECOMMUNICATIONS RESEARCH INSTITUTE, Daejeon-City (KR)

(21) Appl. No.: 12/606,336

(22) Filed: Oct. 27, 2009

(51) Int. Cl. H01L 31/042

(52) U.S. Cl. 136/244

(57) ABSTRACT

Provided is a greenhouse including transparent solar batteries disposed on an outer wall of the greenhouse. Since the transparent solar batteries are disposed on an outer wall of the greenhouse, the greenhouse may generate pollution-free energy while allowing greenhouse cultivation.

### BACKGROUND OF THE INVENTION

1. Field of the Invention

The present invention relates to a greenhouse using a solar battery.

2. Description of the Related Art

Conventional greenhouses are made of glass or vinyl through which light transmits, and plants are cultivated therein. That is, the greenhouse, which is configured so that the green house is exposed to lots of sunlight, only receives the sunlight passively, and does not actively generate energy by using the sunlight.

### SUMMARY OF THE INVENTION

The present invention provides a greenhouse capable of generating pollution-free energy and cultivating plants therein by using a solar battery.

According to an aspect of the present invention, there is provided a greenhouse using a solar battery, the greenhouse including: amorphous silicon solar batteries or dye-sensitized solar cells (DSC) arranged in an array; and an outer wall formed by arranging the solar batteries with predetermined intervals therebetween.

### BRIEF DESCRIPTION OF THE DRAWINGS

The above and other features and advantages of the present invention will become more apparent by describing in detail exemplary embodiments thereof with reference to the attached drawings in which:

FIG. 1 is a schematic diagram of general solar batteries;

FIG. 2 is a diagram showing an outer wall of a greenhouse having solar batteries, according to an embodiment of the present invention;

FIG. 3 are front views of the greenhouse shown in FIG. 2, according to other embodiments of the present invention;

FIG. 4 is a diagram showing solar cells for adjusting a light transmittance of the greenhouse; and

FIG. 5 is a diagram showing a solar battery including a hot-wire on a surface thereof, according to an embodiment of the present invention.

### DETAILED DESCRIPTION OF THE INVENTION

The present invention will now be described more fully with reference to the accompanying drawings, in which exemplary embodiments of the invention are shown.

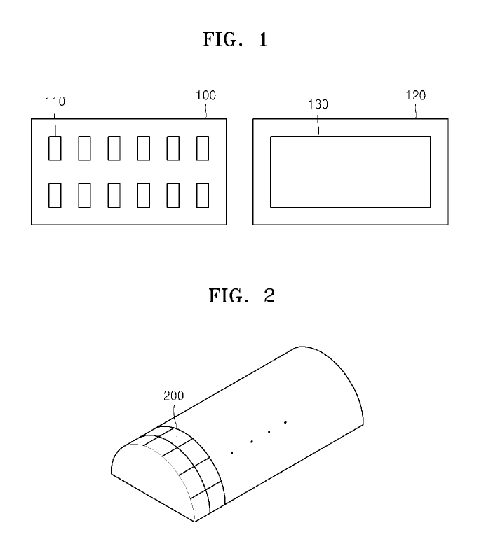

FIG. 1 is a diagram showing general solar batteries.

In FIG. 1, a solar battery located on the left side of the drawing is an amorphous silicon solar battery in which a plurality of solar cells 110 are arranged on a substrate 100 in an array. A solar battery located on the right side of the drawing is a dye-sensitized solar cell (DSC) in which a solar cell 130 is disposed on a substrate 120. In the DSC, the solar cell 130 may have a size corresponding to that of the substrate 120. Embodiments of the present invention may use various types of solar batteries that have been developed so far, as well as the general solar batteries shown in FIG. 1.

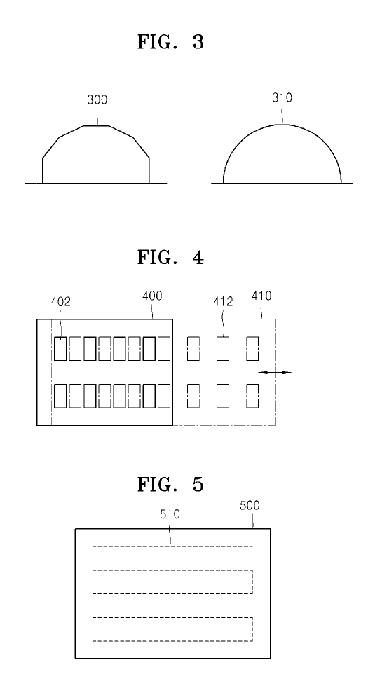

FIG. 2 is a diagram showing an outer wall of a greenhouse having solar batteries 200, according to an embodiment of the present invention, FIG. 3 are front views of the greenhouse shown in FIG. 2, according to other embodiments of the present invention, FIG. 4 is a diagram showing solar cells 402 and 412 for adjusting a light transmittance of the greenhouse, and FIG. 5 shows an example of a solar battery 500 including a hot-wire 510 on a surface thereof, according to an embodiment of the present invention. Hereinafter, the embodiments of the present invention will be described with reference to FIGS. 2 through 5.

Referring to FIG. 2, the outer wall of the greenhouse is surrounded by the solar batteries 200. That is, conventional greenhouses are formed of glass or vinyl; however, the greenhouse of the present embodiment is surrounded by the solar batteries 200 that are transparent. According to other embodiments of the present invention, as illustrated in FIG. 3, the greenhouse may be formed of a plurality of flat solar batteries 300 which are connected to each other and attached to the outer wall of the greenhouse without bending the solar batteries 300, or may be formed of bendable solar batteries 310 that are formed correspondingly on the outer wall of the greenhouse. That is, when the amorphous silicon solar battery or the DSC shown in FIG. 1 includes a bendable substrate, a greenhouse of rounded shape may be formed.

The solar batteries 200 may surround the entire portion of the greenhouse as shown in FIG. 2. Otherwise, the solar batteries 200 may be arranged in an array and conventional materials (for example, glass, vinyl, and transparent plastic) may be connected between the solar batteries 200.

Cultivating conditions may vary depending on plants being cultivated in the greenhouse, and thus, the solar batteries 200 that have a light transmittance suitable for the kind of plant being cultivated in the greenhouse may be used. In order to adjust the light transmittance to be suitable for the plants being cultivated in the greenhouse, the solar batteries 200 on the greenhouse may be arranged in a double-layered structure as shown in FIG. 4. For example, in order to reduce the light transmittance, the solar cells 402 and 412 of two solar batteries 400 and 410 are arranged alternately, and in order to increase the light transmittance, the solar cells 402 and 412 respectively of solar batteries 400 and 410 are disposed to overlap each other. Therefore, an intensity of the light transmitted by the solar batteries 400 and 410 may be adjusted.

On the other hand, when heavy snow falls in the winter, the weight applied to the greenhouse increases and the greenhouse may collapse. In order to prevent the greenhouse from collapsing, the strength of the greenhouse structure needs to be increased. In addition, it may be inconvenient to clean the snow piled up on the solar batteries 400 and 410. Therefore, the solar battery 500 may include the hot-wire 510 on a surface thereof so as to melt the snow that falls on the surface thereof when it snows, and to prevent the snow from piling. Sensing of the snow may be performed using various sensors, as well as by a human being. In addition, the energy supplied to the hot-wire 510 may be generated and accumulated by the solar battery 500.

In FIG. 5, the solar battery 500 includes the hot-wire 510, but the present embodiment is not limited thereto, and thus, a material which generates heat on receiving energy may be coated on the surface of the solar battery 500 so that the heat may be generated from the entire surface of the solar battery 500 so that the snow may be melted efficiently. For example, a transparent plate having a heat generating function by using a carbon nano-tube (CNT) may be disposed on the surface of the solar battery 500.

According to a greenhouse of the present invention, plants are cultivated in the greenhouse, and moreover, pollution-free energy may be generated by solar batteries disposed on the outer wall of the greenhouse.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A greenhouse using solar batteries, the greenhouse comprising:
amorphous silicon solar batteries or dye-sensitized solar cells (DSC) arranged in an array; and
an outer wall formed by arranging the solar batteries with predetermined intervals therebetween.

2. The greenhouse of claim 1, wherein a transparent plate for generating heat by using a carbon nano-tube is disposed on surfaces of the solar batteries.

3. The greenhouse of claim 1, wherein the solar batteries are arranged in double-layered structure and solar cells of the solar batteries are arranged alternately so that a light transmittance of the greenhouse may vary depending on an overlapping degree of the double-layered solar batteries.
